(19) United States
(12) Patent Application Publication
(10) Pub. No.: US 2015/0236224 A1
(43) Pub. Date: Aug. 20, 2015

(54) LIGHT EMITTING DEVICE PACKAGE AND METHOD OF FABRICATING THE SAME

(71) Applicant: SAMSUNG ELECTRONICS CO., LTD., Suwon-Si (KR)

(72) Inventors: Chang-Hoon KWAK, Hwaseong-si (KR); Hak-Hwan KIM, Suwon-Si (KR); Byung-Kwon YOON, Hwaseong-si (KR); Hyo-Jin LEE, Hwaseong-si (KR); Han-Na HEO, Suwon-si (KR)

(21) Appl. No.: 14/607,864

(22) Filed: Jan. 28, 2015

(30) Foreign Application Priority Data
Feb. 14, 2014 (KR) 10-2014-0017352

(51) Int. Cl. H01L 33/50; F21V 8/00; H01L 33/62

(52) U.S. Cl. CPC H01L 33/504; H01L 33/505; H01L 33/62; G02B 6/0073

(57) ABSTRACT

Provided are a light emitting device package and a method of fabricating the same. The package includes a package body including a lead frame, a light emitting device mounted on the package body, a bonding wire configured to electrically connect an electrode formed on a top surface of the light emitting device with the lead frame, a phosphor sheet attached on the light emitting device, and a phosphor molding portion to cover the light emitting device and the phosphor sheet.

### CROSS-REFERENCE TO RELATED APPLICATION

This application claims priority under 35 U.S.C. §119 to Korean Patent Application No. 10-2014-0017352 filed on Feb. 14, 2014, the disclosure of which is hereby incorporated by reference in its entirety.

### BACKGROUND

1. Technical Field

The instant application relates to a light emitting device package and a method of fabricating the same.

2. Description of Related Art

In general, a light emitting device package can include a phosphor molding portion in which phosphors are dotted by dispensing a transparent resin having mixed red and green phosphors on the light emitting device. In such the light emitting device package, white light has been embodied by which a red or green phosphor included in a phosphor molding portion is excited by light emitted from the light emitting device.

At this moment, light emitted from the green phosphor can excite a red phosphor to emit red light. Accordingly, the green light is not emitted properly because the green light emitted from the green phosphor is absorbed by the red phosphor. In addition, the control of distribution and amount of the red and green phosphors is not easy and thus light distribution characteristics and color dispersion of the light emitting device package can be degraded..

### SUMMARY

In one general aspect, the instant application describes a light emitting device package comprising a package body including a lead frame, a light emitting device mounted on the package body, a bonding wire configured to electrically connect an electrode formed on a top surface of the light emitting device with the lead frame, a phosphor sheet attached on the light emitting device, and a phosphor molding portion to cover the light emitting device and the phosphor sheet.

The above general aspect may include one or more of the following features. The package may further include a cavity located in the middle of the package body. The phosphor sheet may have the same area as the top surface of the light emitting device. Side surfaces of the phosphor sheet may be vertically arranged with respect to side surfaces of the light emitting device. The lead frame may include a first lead frame and a second lead frame which are exposed in the cavity. The light emitting device may be mounded on the first lead frame. The electrode may include a first electrode and a second electrode which are exposed on the top surface thereof. The bonding wire may include a first bonding wire and a second bonding wire. The first electrode may be electrically connected with the first lead frame using the first bonding wire. The second electrode may be electrically connected with the second lead frame using the second bonding wire.

The package may further include a chip adhesive member interposed between the light emitting device and the first lead frame. The chip adhesive member may surround a part of side surfaces of the light emitting device. The package may further include a Zener diode disposed on the second lead frame. The Zener diode may include an upper electrode electrically connected with the first lead frame and a lower electrode electrically connected with the second lead frame. The upper electrode of the Zener diode may be electrically connected with the first lead frame using a bonding wire. The lower electrode may be electrically connected with the second lead frame using a conductive adhesive member.

In another general aspect, the instant application describes a light emitting device package comprising a package body including a cavity and first and second lead frames exposed on a bottom of the cavity, a light emitting device including first and second electrodes mounted in the cavity and formed on a top surface thereof, a Zener diode mounted on the second lead frame and having an upper electrode and a lower electrode, first and second bonding wires to electrically connect the first and second electrodes of the light emitting device with the first and second lead frames, respectively, and a third bonding wire to electrically connect the upper electrode of the Zener diode with the second lead frame, a red phosphor sheet attached on the light emitting device, and a green phosphor molding portion filling the cavity.

The above general aspect may include one or more of the following features. The red phosphor sheet may not cover side surfaces of the light emitting device. The green phosphor molding portion may cover the side surfaces of the light emitting device and side surfaces of the red phosphor sheet.

In another general aspect, the instant application describes a light emitting device package comprising a package body including a lead frame; a light emitting device mounted on the package body; a bump configured to electrically connect an electrode formed on a bottom surface of the light emitting device with the lead frame; a phosphor sheet attached on the light emitting device; and a phosphor molding portion to cover the light emitting device and the phosphor substance sheet.

The above general aspect may include one or more of the following features. The package may further include a cavity located in the middle of the package body. The phosphor sheet may have the same area as the top surface of the light emitting device. Side surfaces of the phosphor sheet may be vertically arranged with respect to side surfaces of the light emitting device. The lead frame may include a first lead frame and a second lead frame which are exposed in the cavity.

### BRIEF DESCRIPTION OF THE DRAWINGS

FIG. 1A is a top view of a light emitting device package in accordance with one implementation of the instant application;

FIG. 1B is a cross-sectional view taken along line I-I shown in FIG. 1A;

FIG. 2A is a top view of a light emitting device package in accordance with another implementation of the instant application;

FIG. 2B is a cross-sectional view taken along line II-II shown in FIG. 2A;

FIG. 3A is a top view of a light emitting device package in accordance with another implementation of the instant application;

FIG. 3B is a cross-sectional view taken along line III-III shown in FIG. 3A;

FIGS. 4A to 4I are diagrams showing a method of fabricating a light emitting device package in accordance with the implementation of the instant application shown in FIGS. 1A and 1B;

FIGS. 5A to 5F are diagrams showing a method of fabricating a light emitting device package in accordance with the implementation of the instant application shown in FIGS. 2A and 2B;

FIGS. 6A to 6C are diagrams showing a method of fabricating a light emitting device package in accordance with the implementation of the instant application shown in FIGS. 3A and 3B;

FIG. 7A is a schematic diagram illustrating a light emitting module including at least one of light emitting device packages in accordance with various implementations of the instant application;

FIG. 7B is a schematic diagram illustrating a back-light unit including at least one of light emitting device packages in accordance with various implementations of the instant application; and

FIG. 7C is a schematic diagram illustrating a device assembly including at least one of light emitting device packages in accordance with various implementations of the instant application.

### DETAILED DESCRIPTION

Hereinafter, exemplary implementations of the present disclosure will be described in detail with reference to the accompanying drawings. The disclosure may, however, be exemplified in many different forms and should not be construed as being limited to the specific implementations set forth herein. Rather, these implementations are provided so that this disclosure will be thorough and complete, and will fully convey the scope of the disclosure to those skilled in the art.

In the drawings, the sizes and relative sizes of layers and regions may be exaggerated for clarity. The terminology used herein to describe various implementations is not intended to limit the scope of the instant application. The articles “a,” “an,” and “the” are singular in that they have a single referent, however, the use of the singular form in the present document should not preclude the presence of more than one referent. In other words, elements of the invention referred to in the singular may number one or more, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

It will be understood that when an element or layer is referred to as being “on,” “connected to,” or “coupled to” another element or layer, it can be directly on, connected, or coupled to the other element or layer or intervening elements or layers may be present. In contrast, when an element is referred to as being “directly on,” “directly connected to,” or “directly coupled to” another element or layer, there are no intervening elements or layers present. Like numerals refer to like elements throughout. As used herein, the term “and/or” includes any and all combinations of one or more of the associated listed items.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

Implementations are described herein with reference to cross-sectional illustrations that are schematic illustrations of idealized implementations and intermediate structures. As such, variations from the shapes of the illustrations as a result, for example, of manufacturing techniques and/or tolerances, are to be expected. Thus, implementations should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

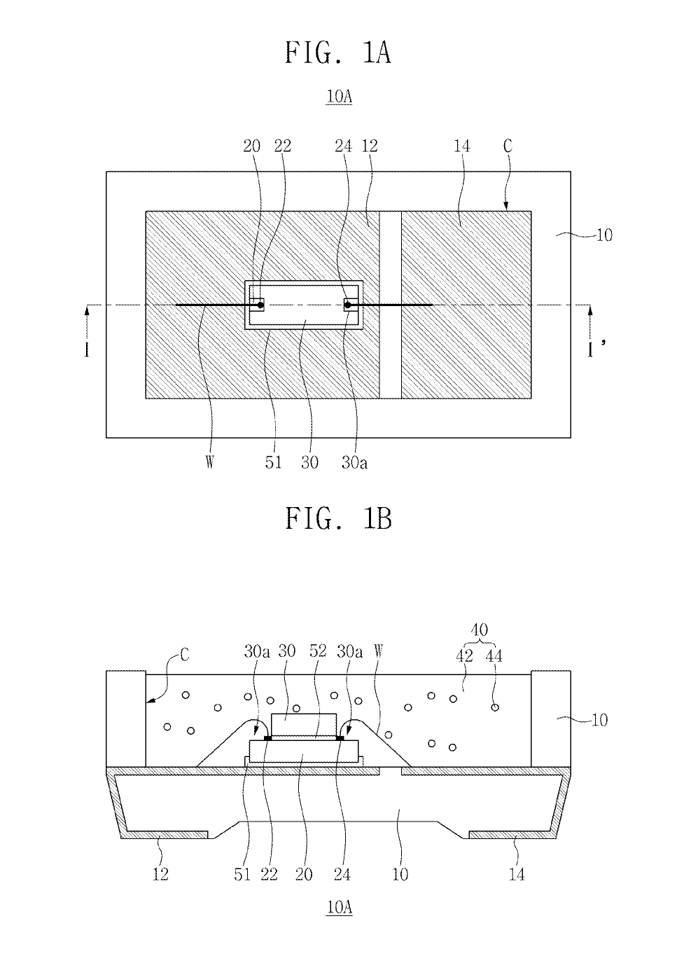

FIG. 1A is a top view of a light emitting device package in accordance with one implementation of the instant application. FIG. 1B is a cross-sectional view taken along line I-I shown in FIG. 1A. For a sake of brevity and an easier understanding, in FIG. 1A, a phosphor molding portion 40 in FIG. 1B is omitted. Referring to FIGS. 1A and 1B, a light emitting device package 10A includes a package body 10 including lead frames 12 and 14, a light emitting device 20, a phosphor sheet 30 and a phosphor molding portion 40. In addition, the light emitting device package 10A further includes adhesive members 51 and 52 and a plurality of bonding wires W.

The package body 10 as a non-conductor which mounts and supports the light emitting device 20, may have a cavity C located in the middle of the package body 10. The package body 10 may include first and second lead frames 12 and 14 exposed in the cavity C. For example, a portion of the first lead frame 12 and a portion of the second lead frame 14 are exposed in the cavity C. The first and second lead frames 12 and 14 may be disposed to be electrically separated from each other on the package body 10. Further, the bottom of the cavity C may have the same horizontal surface (coplanar) as the surfaces of the first and second lead frames 12 and 14. In FIG. 1B, the first and second lead frames 12 and 14 exposed in the cavity C are connected to the bottom of the package body 10, but it is not limited thereto and it may be connected to side surfaces of the package body 10. The package body 10 may include polyphthalamide (PPA). The first and second lead frames 12 and 14 may include copper (Cu), aluminum (Al), a copper alloy, or an aluminum alloy.

The light emitting device 20 may be mounted on the package body 10 in the cavity C. For example, the light emitting device 20 may be mounted on the exposed portion of the first lead frame 12. The light emitting device 20 may include a first electrode 22 and a second electrode 24 formed on one surface thereof. The light emitting device 20 may include a blue light emitting diode (LED) which outputs blue light.

The plurality of bonding wires W may bond the electrodes 22 and 24 formed on the top surface of the light emitting device 20 with the lead frames 12 and 14, respectively. For example, the first electrode 22 of the light emitting device 20 may be electrically connected with the first lead frame 12 using a corresponding bonding wire W, and the second electrode 24 of the light emitting device 20 may be electrically connected with the second lead frame 14 using a corresponding bonding wire W. For example, the bonding wires W may include gold (Au).

The phosphor sheet 30 may be attached on the top surface of the light emitting device 20. The phosphor sheet 30 may have a substantially uniform thickness. Side surfaces of the phosphor sheet 30 may be vertically arranged with respect to side surfaces of the light emitting device 20. The phosphor sheet 30 may have the same area as the top surface of the light emitting device 20. The phosphor sheet 30 may not cover the side surfaces of the light emitting device 20. Further, the phosphor sheet 30 may have electrode exposing portions 30a which is partially removed to correspond to locations and shapes of the electrodes 22 and 24 of the light emitting device 20. The electrode exposing portions 30a may be formed at edges or corners in the phosphor sheet 30. The phosphor sheet 30 may include a sheet base resin and a phosphor. For example, the sheet base resin may include any one of polymer silicon, such as phenyl-based silicon and methyl-based silicon, or glass (SiO₂). The phosphor may include various phosphors according to light output from the light emitting device 20. For example, when the light emitting device 20 is a blue LED, a red phosphor sheet 30 including the sheet base resin and a red phosphor may be directly attached on the top surface of the light emitting device 20. The red phosphor may include not only one type of the red phosphor but also a plurality of red phosphors to output light having desired wavelengths according to a light emitting device package to be designed. The red phosphor may include a phosphor in which a peak wavelength is 590 nm or more. For example, the red phosphor may include any one of CaAlSiN₃, CaS or a combination thereof.

The phosphor molding portion 40 may be formed to cover the light emitting device 20 and the phosphor sheet 30. The phosphor molding portion 40 may include a molding base resin 42 and a phosphor 44. For example, the molding base resin 42 may include polymer silicon such as phenyl-based silicon and methyl-based silicon. The phosphor 44 may include various phosphors according to light output from the light emitting device 20 and light emitted from the phosphor sheet 30. For example, when the light emitting device 20 is a blue LED and the phosphor sheet 30 is a red phosphor sheet, a green phosphor molding portion including the molding base resin 42 and a green phosphor 44 may cover the light emitting device 20 and the phosphor sheet 30, and fill the cavity C. Further, the green phosphor molding portion may cover the side surfaces of the light emitting device 20 and side surfaces of the red phosphor sheet. The green phosphor 44 may include not only one type of the green phosphor but also a plurality of green phosphors to output light having desired wavelengths according to a light emitting device package to be designed. The green phosphor 44 may include a phosphor in which a peak wavelength is 560 nm or less. For example, the green phosphor 44 may include any one of Gd₃Al₅O₁₂, SiAlON or a combination thereof.

The adhesive members 51 and 52 may include a chip adhesive member 51 interposed between the package body 10 and the light emitting device 20, and a sheet adhesive member 52 interposed between the light emitting device 20 and the phosphor sheet 30. For example, the chip adhesive member 51 may be interposed between the light emitting device 20 and the first lead frame 12. The chip adhesive member 51 may surround a part of the side surfaces of the light emitting device 20. The chip adhesive member 51 and the sheet adhesive member 52 may include silicon. Further, the chip adhesive member 51 and the sheet adhesive member 52 may include the same material as the sheet base resin used in the phosphor sheet 30.

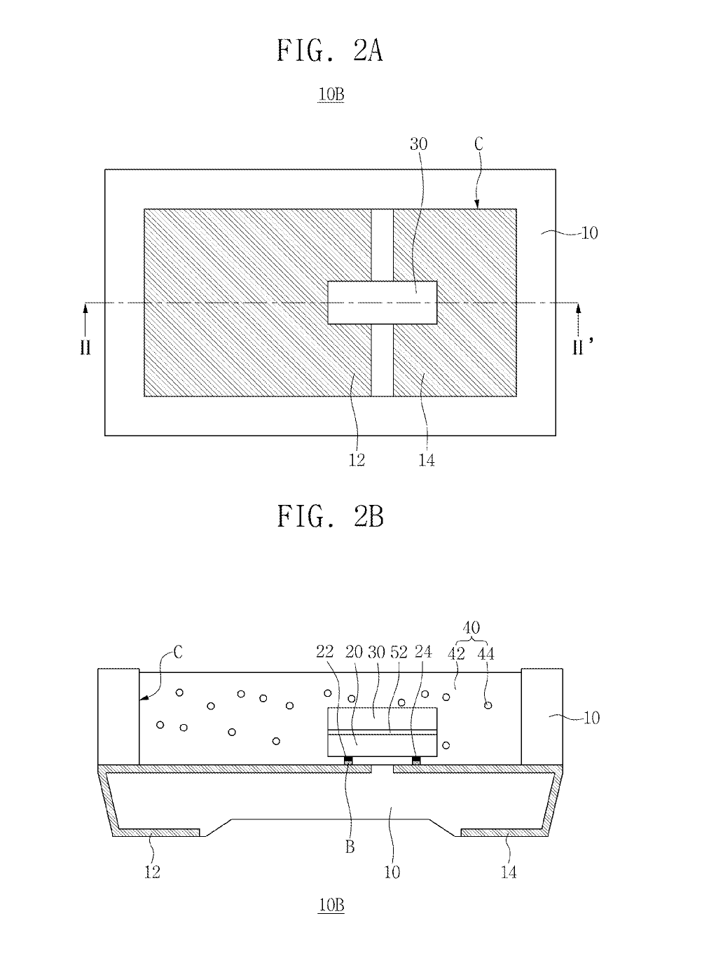

FIG. 2A is a top view of a light emitting device package in accordance with an another implementation of the instant application. FIG. 2B is a cross-sectional view taken along line II-II shown in FIG. 2A. For sake of simplicity and an easier understanding, in FIG. 2A, a phosphor molding portion 40 is omitted. Since a light emitting device package 10B shown in FIGS. 2A and 2B is the same as the light emitting device package 10A shown in FIGS. 1A and 1B except using bumps B instead of the bonding wires W, detailed descriptions of the same elements are omitted for the sake of brevity and simplicity of description.

Referring to FIGS. 2A and 2B, the light emitting device package 10B includes a package body 10 including first and second lead frames 12 and 14 and a cavity C, a light emitting device 20, a phosphor sheet 30 and a phosphor molding portion 40. In addition, the light emitting device package 10B further include adhesive members 51 and 52 and a plurality of bumps B.

The light emitting device 20 may be mounted on the package body 10 in the cavity C. The light emitting device 20 may include electrodes 22 and 24 formed on one surface thereof. For example, the electrodes 22 and 24 may include a first electrode 22 and a second electrode 24 exposed on the bottom surface of the light emitting device 20. The light emitting device 20 may include a blue LED which outputs blue light.

The plurality of bumps B may be flip-chip bond the electrodes 22 and 24 formed the bottom surface of the light emitting device 20 with the lead frames 12 and 14 to be electrically connected to each other, respectively. For example, the first electrode 22 of the light emitting device 20 may be electrically connected with the first lead frame 12 using a corresponding bump B, and the second electrode 24 of the light emitting device 20 may be electrically connected with the second lead frame 14 using a corresponding bump B. For example, the bumps B may include a solder ball, a metal pillar, or a metal pad.

The phosphor sheet 30 may be attached on the top surface of the light emitting device 20. The phosphor sheet 30 may have a substantially uniform thickness. Side surfaces of the phosphor sheet 30 may be vertically arranged with respect to side surfaces of the light emitting device 20. The phosphor sheet 30 may have the same area as the top surface of the light emitting device 20. The phosphor sheet 30 may not cover the side surfaces of the light emitting device 20.

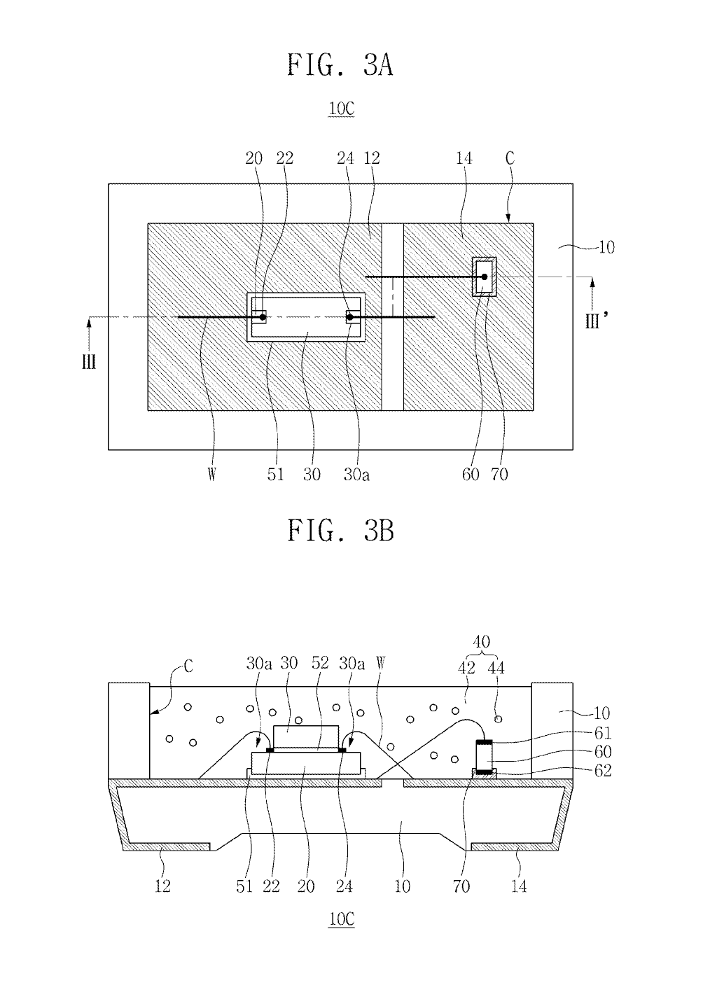

FIG. 3A is a top view of a light emitting device package in accordance with another implementation of the instant application. FIG. 3B is a cross-sectional view taken along line III-III shown in FIG. 3A. For the sake of simplicity and an easier understanding, in FIG. 3A, a phosphor molding portion 40 shown in FIG. 3B is omitted.

Referring to FIGS. 3A and 3B, a light emitting device package 10C includes a package body 10 including first and second lead frames 12 and 14 and a cavity C, a light emitting device 20, a phosphor sheet 30, a phosphor molding portion 40 and a Zener diode 60. In addition, the light emitting device package 10C further includes a plurality of bonding wires W, adhesive members 51 and 52 and a conductive adhesive member 70.

The Zener diode 60 prevents from flowing reverse current generated when a reverse voltage is applied to the light emitting device 20, thereby preventing damage to the light emitting device 20. The Zener diode 60 may be mounted on the package body 10 in the cavity C. For example, the Zener diode 60 may be mounted on the second lead frame 14. The Zener diode 60 may include an upper electrode 61 electrically connected with the first lead frame 12 and a lower electrode 62 electrically connected with the second lead frame 14. The upper electrode 61 and the first lead frame 12 may be electrically connected using a bonding wire W, and the lower electrode 62 and the second lead frame 14 may be electrically connected using a conductive adhesive member 70. The bonding wire W may include gold (Au). The conductive adhesive member 70 may include an anisotropic conductive film (ACF).

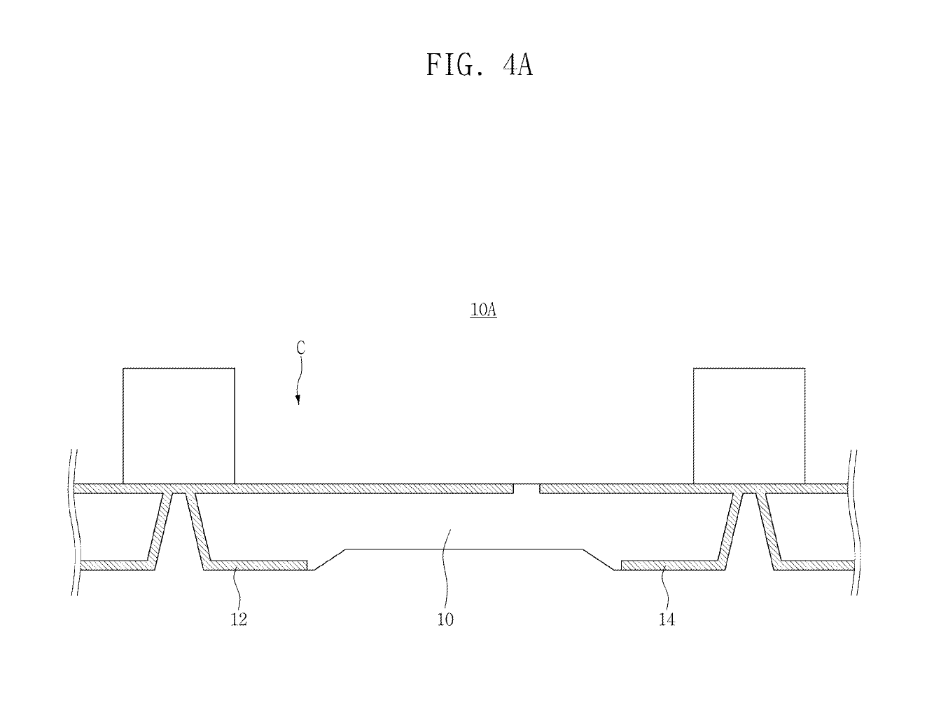

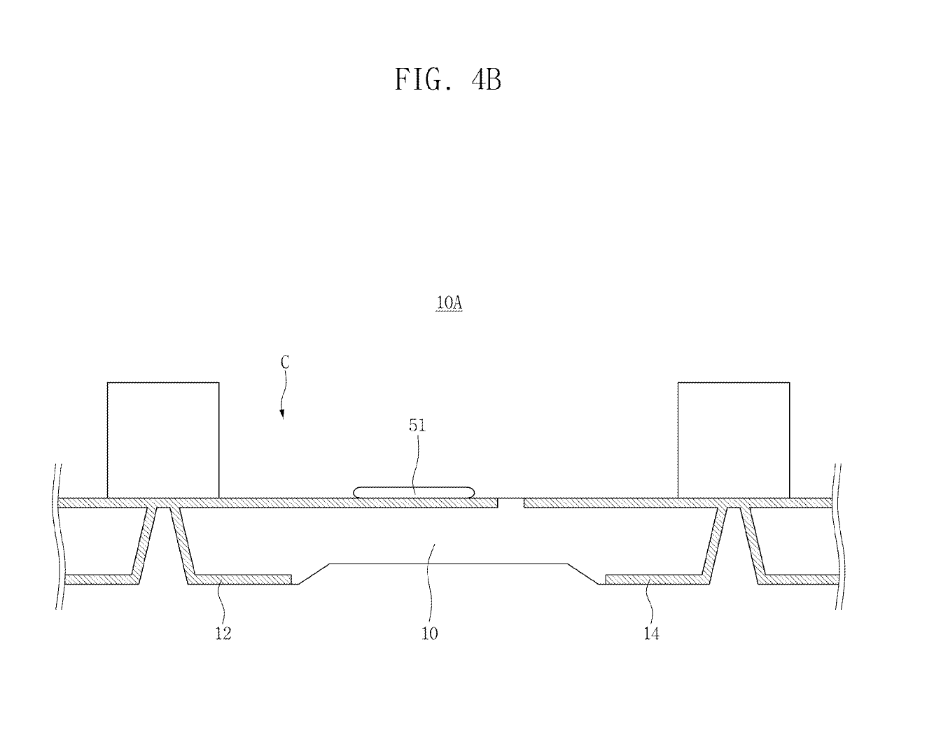

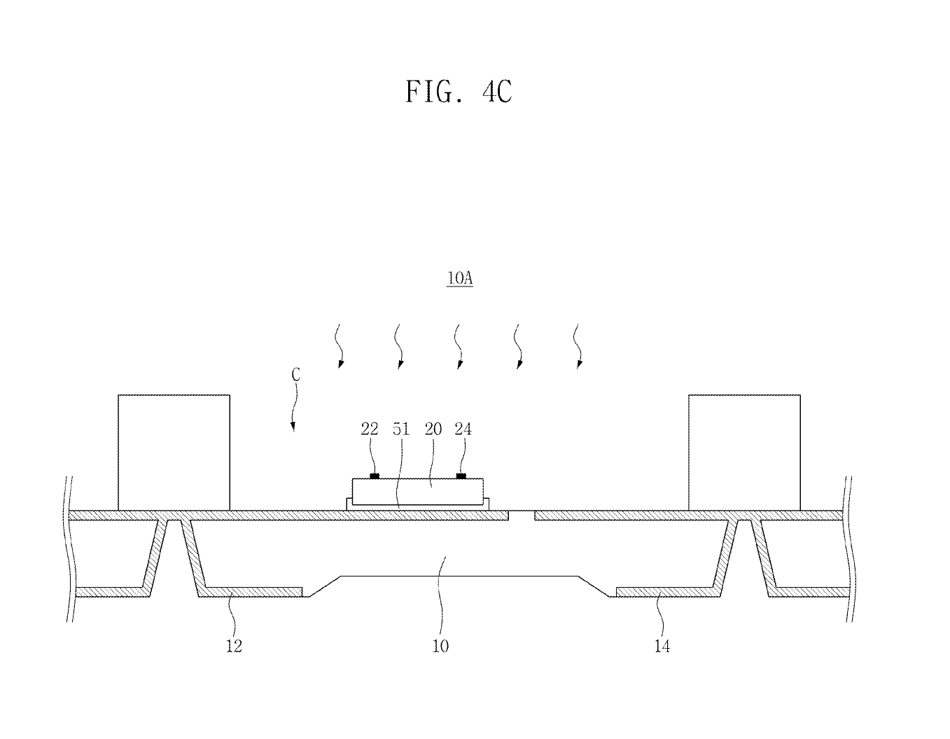

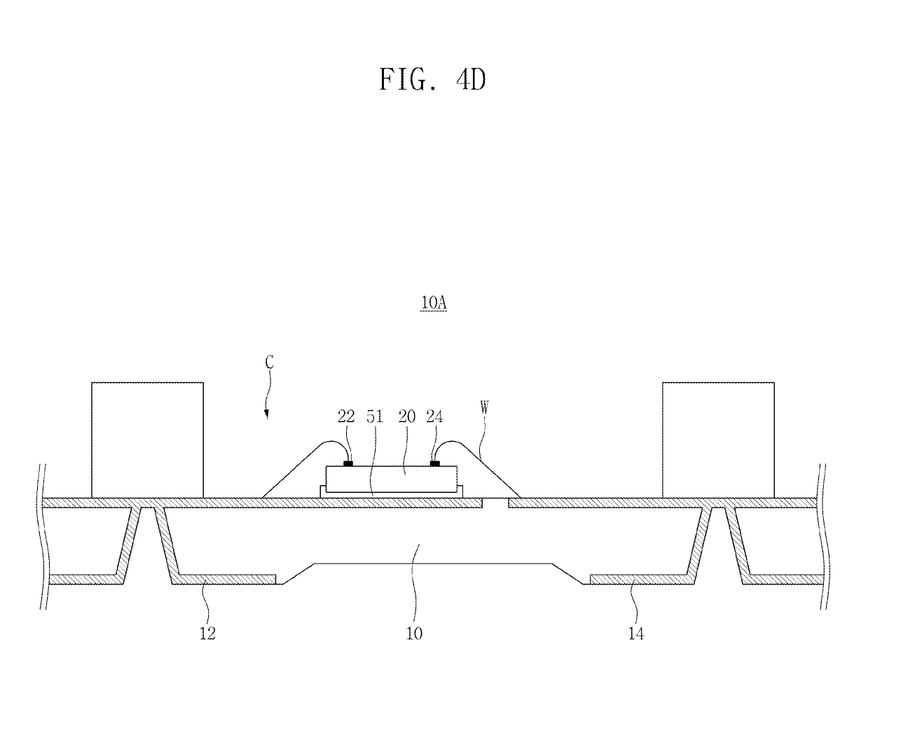

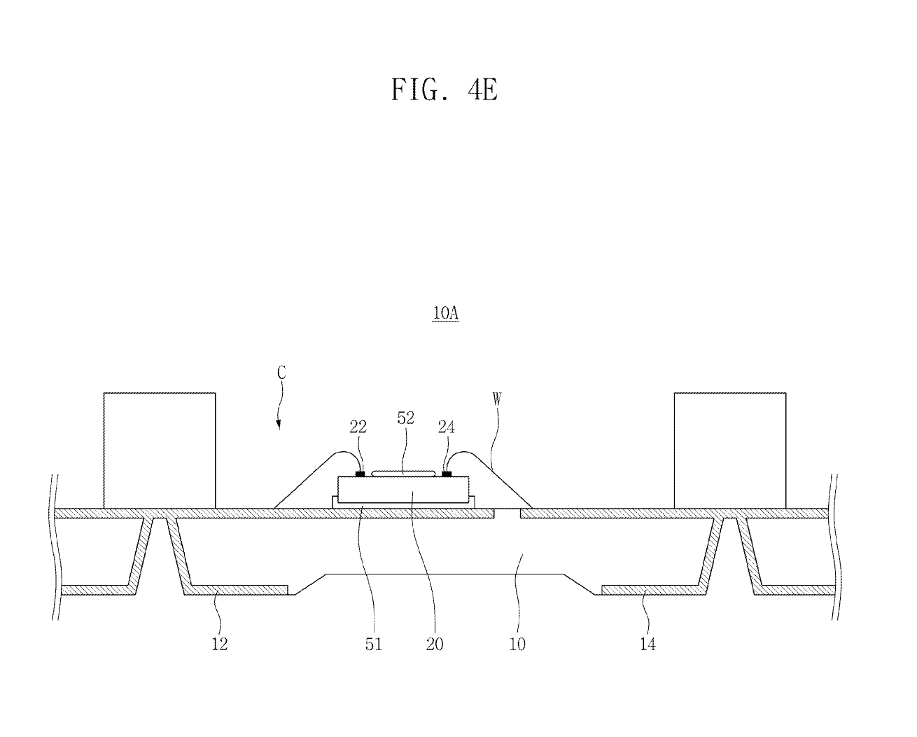

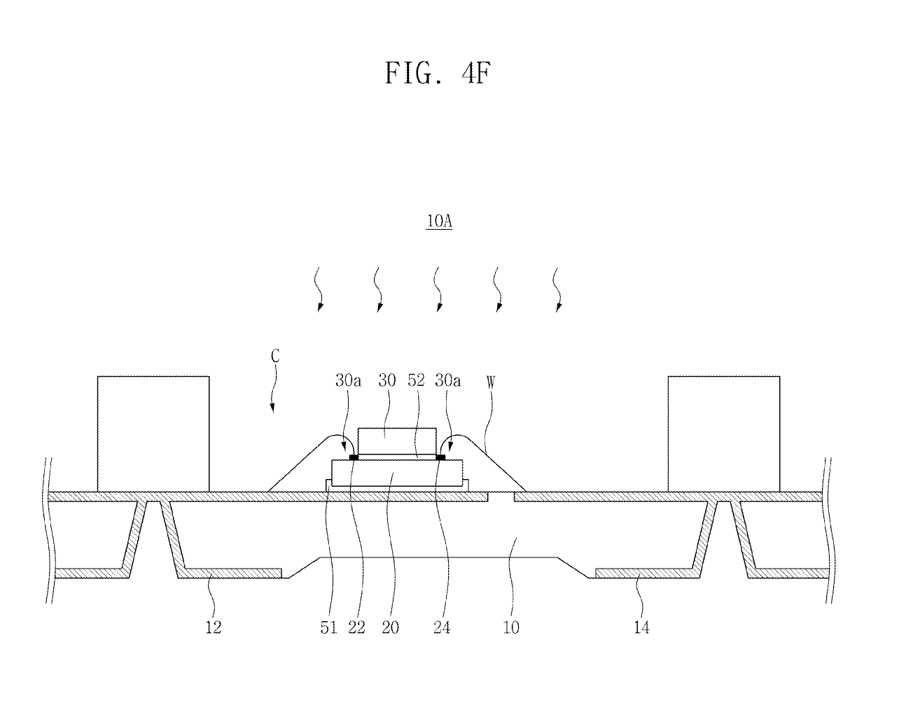

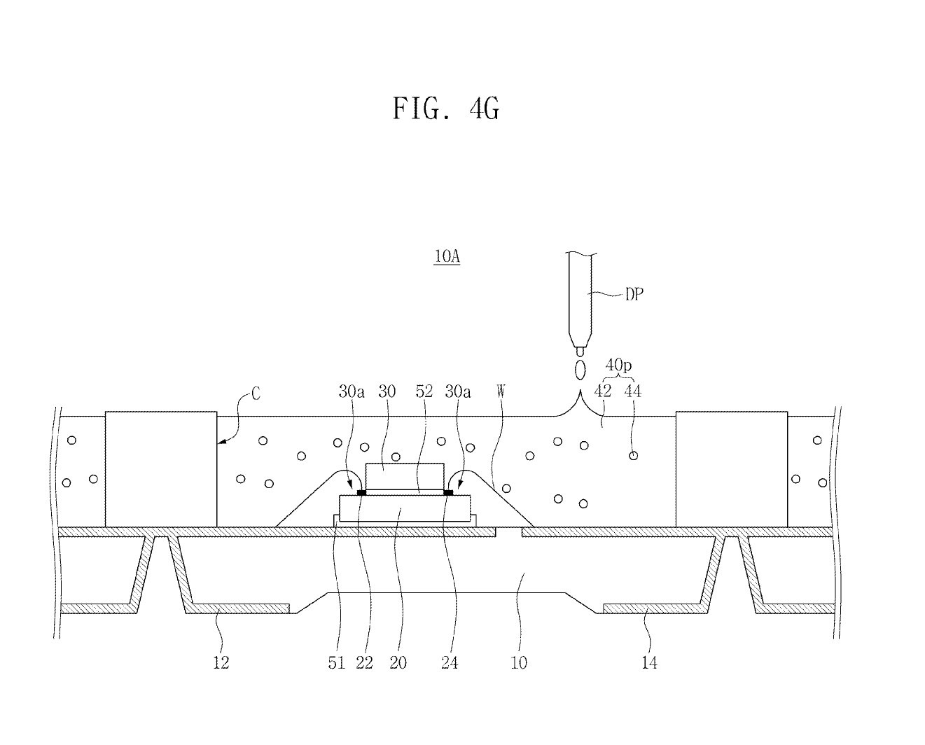

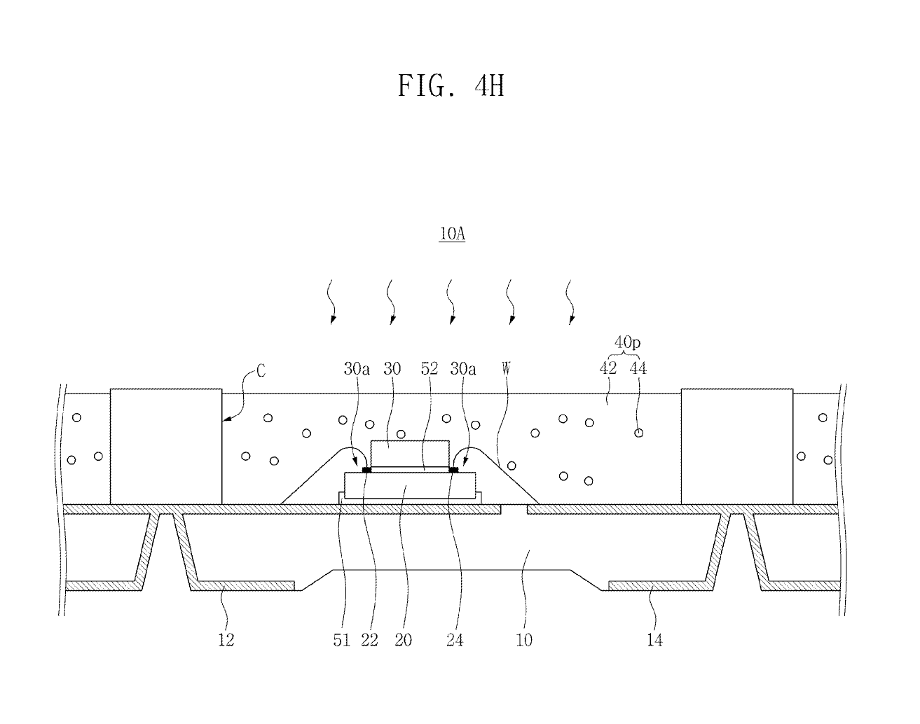

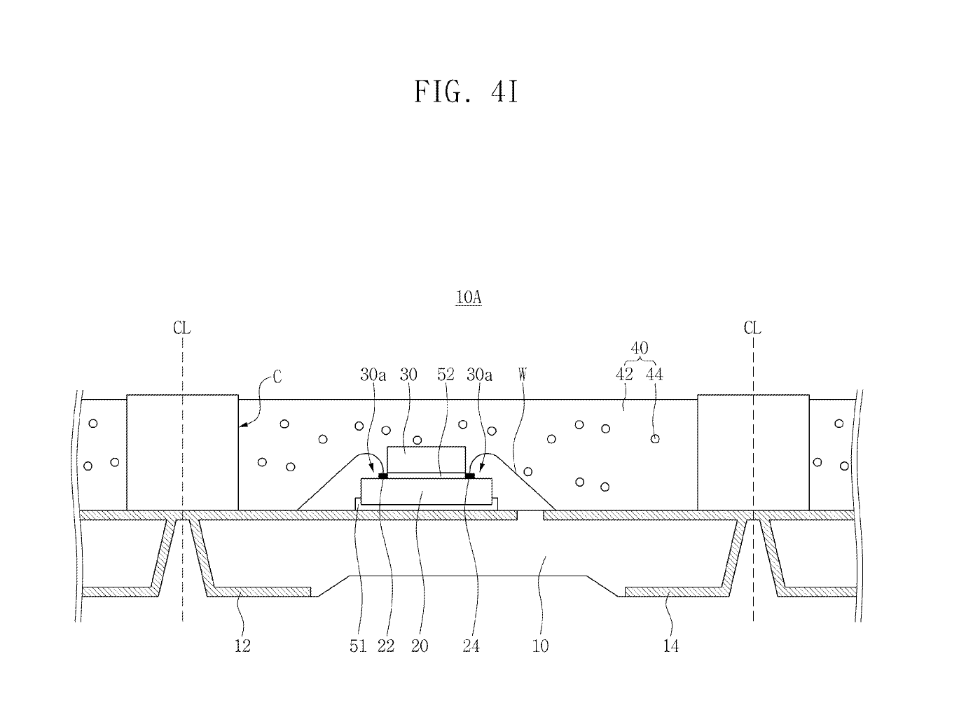

FIGS. 4A to 4I are diagrams showing a method of fabricating the light emitting device package 10A in accordance with an implementation of the instant application shown in FIGS. 1A and 1B.

Referring to FIG. 4A, the method may include forming a plurality of package bodies 10 including a plurality of first and second lead frames 12 and 14 and a cavity C.

The forming of the plurality of package bodies 10 may include injection molding the plurality of package bodies by filling a liquefied resin material in a mold disposed to include the plurality of first and second lead frames 12 and 14. Each of the package bodies 10 may include the cavity C on which a light emitting device 20 is mounted, and surfaces of the first and second lead frames 12 and 14 may be exposed on the bottom of the cavity C.

Referring to FIG. 4B, the method may include providing a chip adhesive member 51 on the package body 10 in the cavity C by performing a stamping process. For example, the chip adhesive member 51 may be provided on the first lead frame 12. The chip adhesive member 51 may have a smaller area than the light emitting device 20. The chip adhesive member 51 may include silicon.

Referring to FIG. 4C, the method may include stacking and pressurizing the light emitting device 20 on the chip adhesive member 51, and heating and curing the chip adhesive member 51. When the light emitting device 20 is stacked and pressurized on the chip adhesive member 51, the chip adhesive member 51 may be spread to contact the bottom of the light emitting device 20. Further, the chip adhesive member 51 may surround a part of side surfaces of the light emitting device 20. The curing of the chip adhesive member 51 may include heating the package body 10 in which the chip adhesive member 51 is provided in a curing oven. For example, the chip adhesive member 51 may be heated for about 1 to 2 hours at about 150° C.

Referring to FIG. 4D, the method may include electrically connecting electrodes 22 and 24 of the light emitting device 20 with the lead frames 12 and 14. The electrically connecting the electrodes 22 and 24 of the light emitting device 20 with the lead frames 12 and 14 may include using bonding wires W. For example, a first electrode 22 of the light emitting device 20 may be electrically connected with the first lead frame 12 using a corresponding bonding wire W, and a second electrode 24 of the light emitting device 20 may be electrically connected with the second lead frame 14 using a corresponding bonding wire W. The bonding wires W may include gold (Au).

Referring to FIG. 4E, the method may include providing a sheet adhesive member 52 on a top surface of the light emitting device 20 by performing a stamping process. The sheet adhesive member 52 may have a smaller area than the top surface of the light emitting device 20. The sheet adhesive member 52 may include silicon.

Referring to FIG. 4F, the method may include stacking and pressurizing a phosphor sheet 30 on the sheet adhesive member 52, and curing the sheet adhesive member 52. The curing of the sheet adhesive member 52 may include heating the package body 10 in which the sheet adhesive member 52 is provided between the light emitting device 20 and the phosphor sheet 30 in a curing oven. For example, the sheet adhesive member 52 may be heated for about 1 to 2 hours at about 150° C.

In another implementation, further referring to FIG. 1B, before the phosphor sheet 30 is attached on the light emitting device 20, the method may further include forming an electrode exposing portion 30a which is partially removed to correspond locations and shapes of the electrodes 22 and 24 of the light emitting device 20 in the phosphor sheet 30. The electrode exposing portion 30a may be formed at edges or corners of the phosphor sheet 30. The electrode exposing portion 30a may be formed by irradiating a laser beam onto a surface of an original phosphor sheet, or formed using a punching device.

The phosphor sheet 30 may include a sheet base resin and a phosphor. The sheet base resin may include any one of polymer silicon, such as phenyl-based silicon and methyl-based silicon, or glass (SiO₂). The phosphor may include a red phosphor. The red phosphor may include a phosphor in which a peak wavelength is 590 nm or more. For example, the red phosphor may include any one of CaAlSiN₃, CaS or a combination thereof.

Referring to 4G, the method may include dispensing a phosphor molding material 40p in the cavity C using a predetermined dispenser DP to cover the light emitting device 20 and the phosphor sheet 30. The phosphor molding material 40p may include a molding base resin 42 and a phosphor 44. The molding base resin 42 may include polymer silicon such as phenyl-based silicon and methyl-based silicon. The phosphor 44 may include a green phosphor 44. The green phosphor 44 may include a phosphor in which a peak wavelength is 560 nm or less. For example, the green phosphor 44 may include any one of Gd₃Al₅O₁₂, SiAlON or a combination thereof.

Referring to FIG. 4H, the method may include curing and converting the phosphor molding material 40p to a phosphor molding portion 40.

Curing and converting the phosphor molding material 40p to the phosphor molding portion 40 may include heating the package body 10 in which the phosphor molding material 40p is dispensed in the cavity C in a curing oven. For example, the phosphor molding material 40p may be heated for about 1 to 2 hours at about 150° C. In this process, the phosphor molding material 40p in a slurry state may be cured and converted to the phosphor molding portion 40. Further, the plurality of light emitting device packages 10A such as described above may be formed in this process.

Referring to FIG. 4I, the method may include separating the plurality of light emitting device packages 10A into individual light emitting device packages 10A along cutting line CL by performing a sawing or scribing process. Thus, the light emitting device package 10A shown in FIGS. 1A and 1B may be formed.

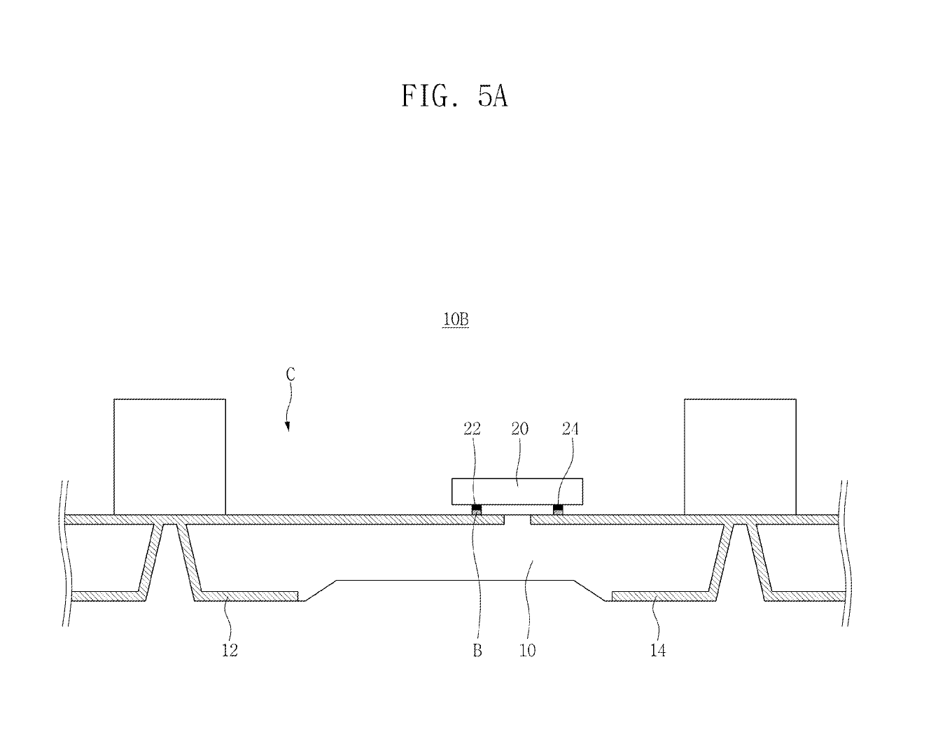

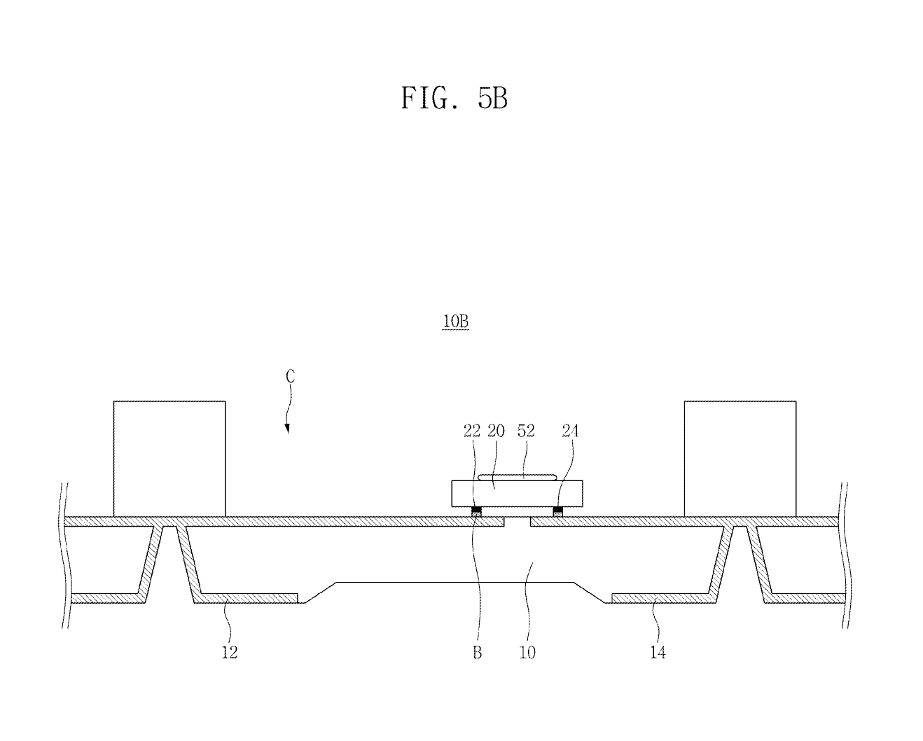

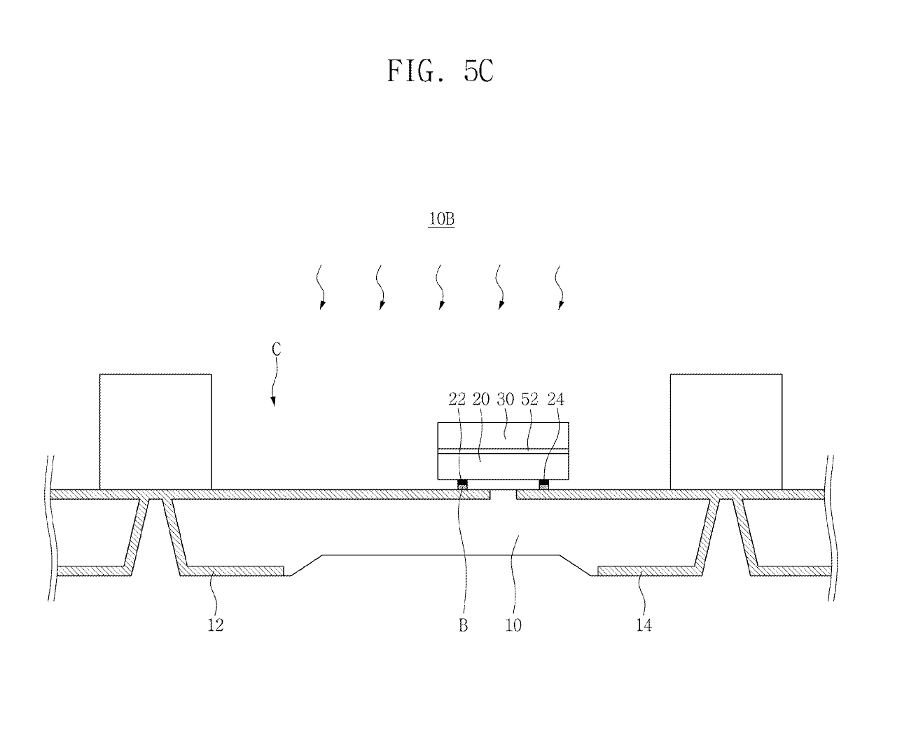

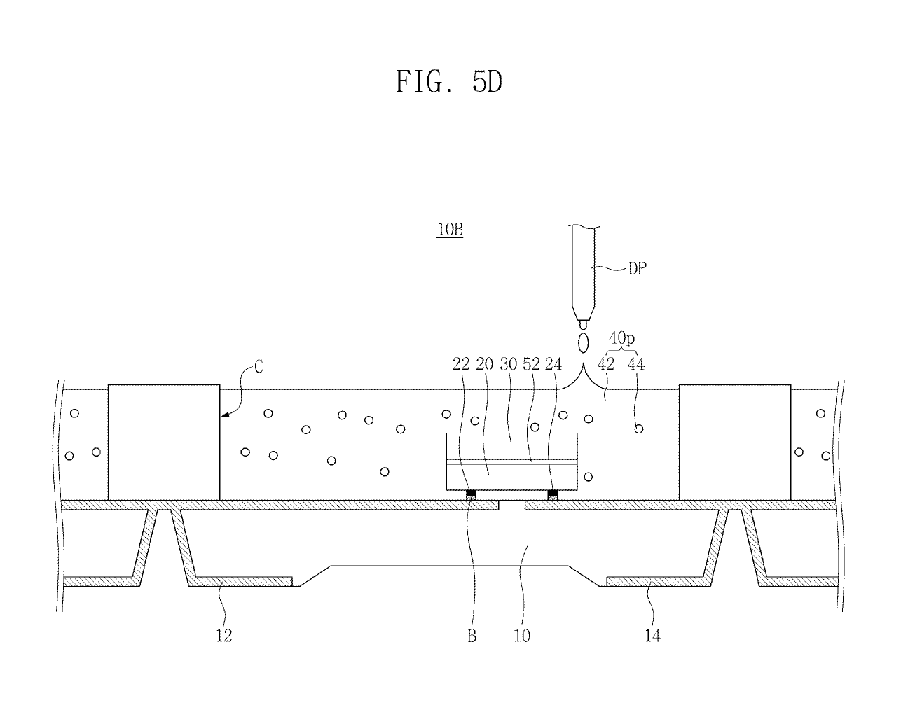

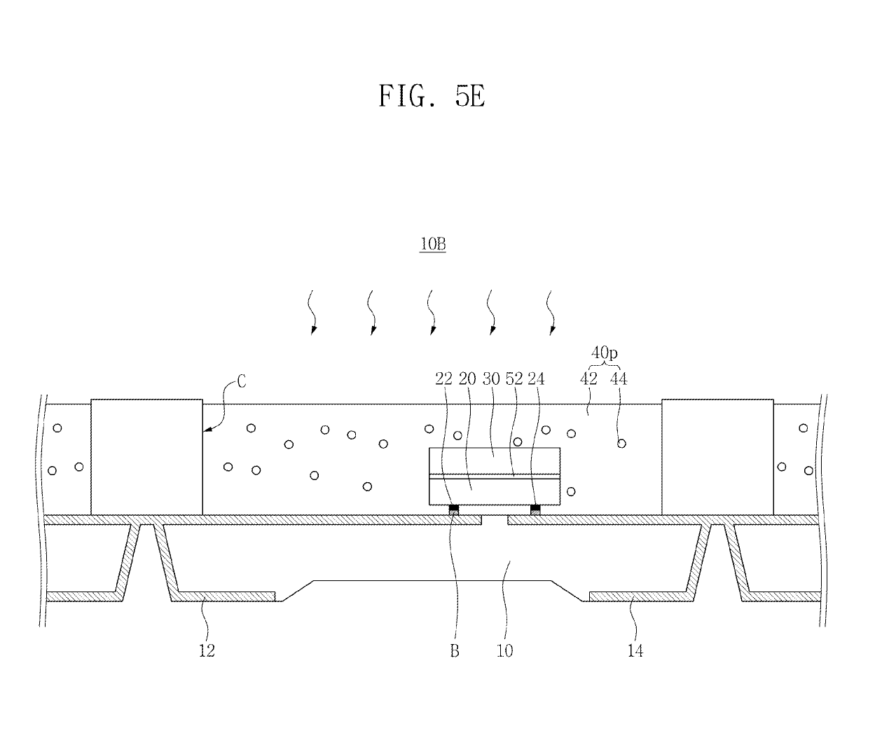

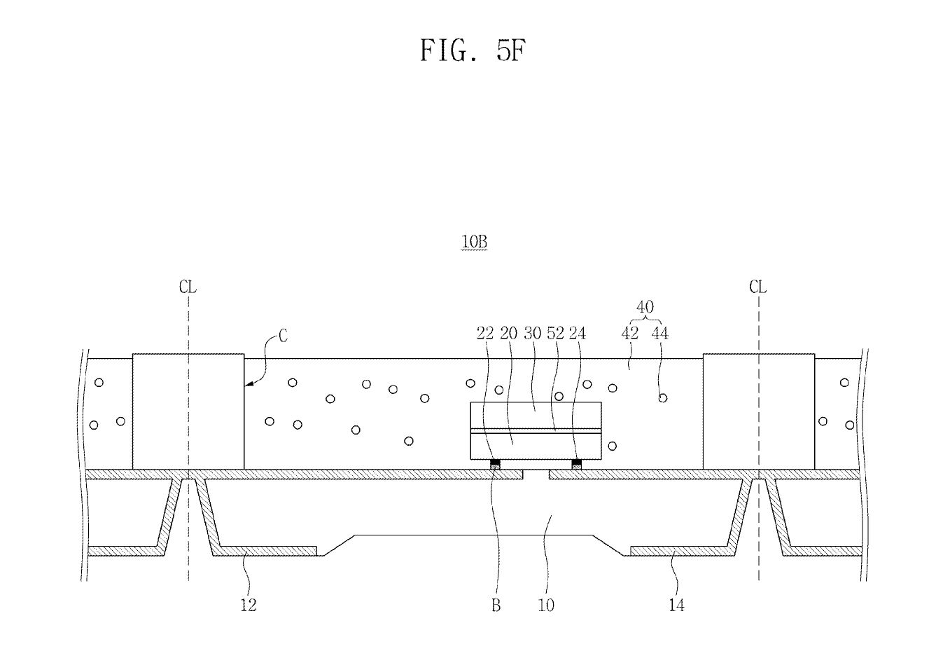

FIGS. 5A to 5F are diagrams showing a method of fabricating a light emitting device package 10B in accordance with the implementation of the instant application shown in FIGS. 2A and 2B. Since the method of fabricating the light emitting device package 10B includes a part of the fabricating method described in FIGS. 4A to 4I, detailed descriptions of the same fabricating method are not described here for the sake of brevity and simplicity of description.

Referring to 5A, the method may include electrically connecting the electrodes 22 and 24 of the light emitting device 20 with the lead frames 12 and 14, respectively. The electrically connecting of the electrodes 22 and 24 of the light emitting device 20 with the lead frames 12 and 14 may include flip-chip bonding using bumps B. For example, the first electrode 22 of the light emitting device 20 may be electrically connected with the first lead frame 12 using a corresponding bump B, and the second electrode 24 of the light emitting device 20 may be electrically connected with the second lead frame 14 using a corresponding bump B. The bumps B may be formed on the lead frames 12 and 14 in a region on which the light emitting device 20 may be mounted, or formed on the electrodes 22 and 24 of the light emitting device 20 in advance. The bumps B may include a solder ball, a metal pillar, or a metal pad.

Referring to FIG. 5B, the method may include providing a sheet adhesive member 52 on top surface of the light emitting device 20 by performing a stamping process. The sheet adhesive member 52 may have a smaller area than the top surface of the light emitting device 20. The sheet adhesive member 52 may include silicon.

Referring to FIG. 5C, the method may include stacking and pressurizing a phosphor sheet 30 on the sheet adhesive member 52, and curing the sheet adhesive member 52. When the phosphor sheet 30 is stacked and pressurized on the sheet adhesive member 52, the sheet adhesive member 52 may be spread to contact the bottom of the phosphor sheet 30. The curing of the sheet adhesive member 52 may include heating the package body 10 in which the sheet adhesive member 52 is provided between the light emitting device 20 and the phosphor sheet 30 in a curing oven. For example, the sheet adhesive member 52 may be heated for about 1 to 2 hours at about 150° C. The phosphor sheet 30 may include a sheet base resin and a phosphor. The sheet base resin may include any one of polymer silicon, such as phenyl-based silicon and methyl-based silicon, or glass (SiO₂). The phosphor may include a red phosphor. The red phosphor may include phosphor in which a peak wavelength is 590 nm or more. For example, the red phosphor may include any one of CaAlSiN₃, CaS or a combination thereof.

Referring to FIG. 5D, the method may include dispensing a phosphor molding material 40p in the cavity C using a predetermined dispenser DP to cover the light emitting device 20 and the phosphor sheet 30. The phosphor molding material 40p may include a base resin 42 for molding and a phosphor 44. The molding base resin 42 may include polymer silicon such as phenyl-based silicon and methyl-based silicon. The phosphor 44 may include a green phosphor 44. The green phosphor 44 may include a phosphor in which a peak wavelength is 560 nm or less. For example, the green phosphor 44 may include any one of Gd₃Al₅O₁₂, SiAlON or a combination thereof.

Referring to FIG. 5E, the method may include curing and converting the phosphor molding material 40p to a phosphor molding portion 40.

Curing and converting the phosphor molding material 40p to the phosphor molding portion 40 may include heating the package body 10 in which the phosphor molding material 40p is dispensed in the cavity C in a curing oven. For example, the phosphor molding material 40p may be heated for about 1 to 2 hours at about 150° C. In this process, the phosphor molding material 40p in a slurry state is cured and converted to the phosphor molding portion 40. Further, the plurality of light emitting device packages 10B such as described above may be formed in this process.

Referring to FIG. 5F, the method may include separating the plurality of light emitting device packages 10B into individual light emitting device packages 10B along cutting line CL by performing a sawing or scribing process. Thus, the light emitting device package 10B shown in FIGS. 2A and 2B may be formed.

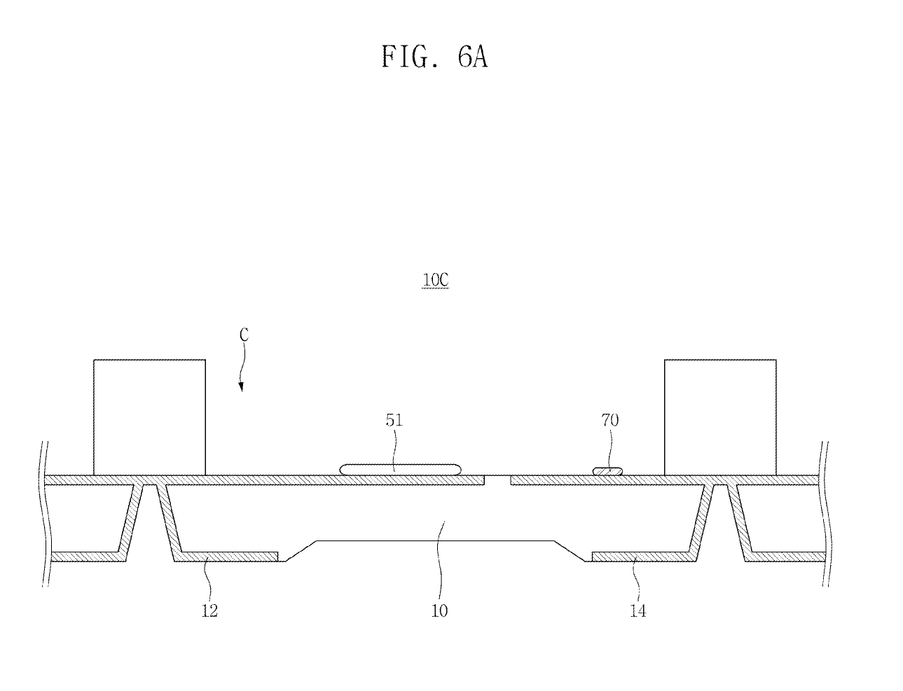

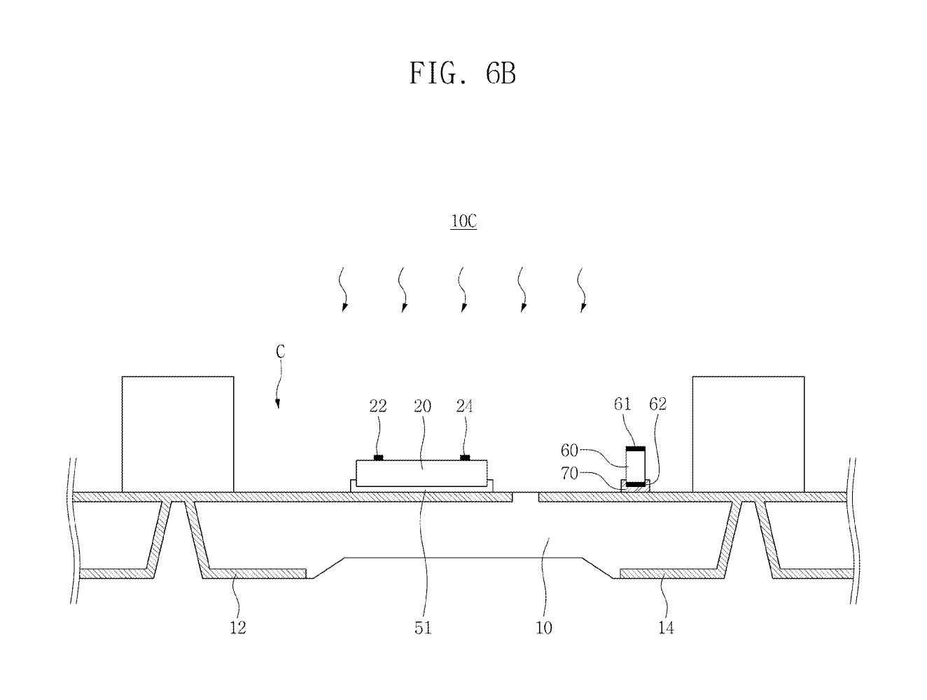

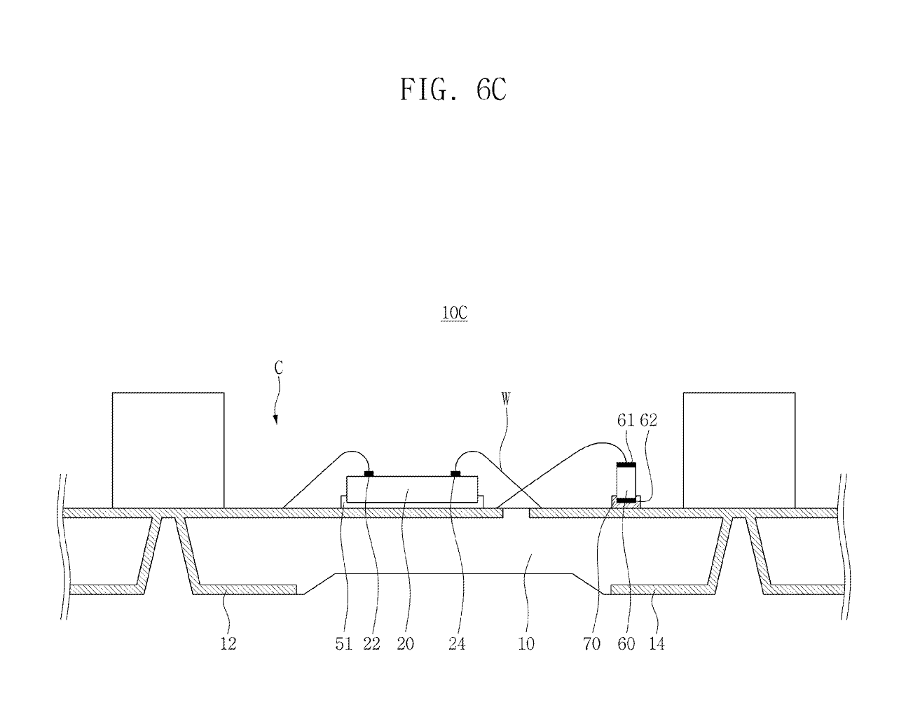

FIGS. 6A to 6C are diagrams showing a method of fabricating a light emitting device package in accordance with the implementation of the instant application shown in FIGS. 3A and 3B. Since the method of fabricating the light emitting device package 10C is the same as the method of fabricating the light emitting device package 10A shown in FIGS. 4A to 4I except further including mounting a Zener diode 60, detailed descriptions of the same fabricating method are omitted for the sake of brevity and simplicity of description.

Referring to FIG. 6A, the method may include providing a conductive adhesive member 70 on the second lead frame 14 by performing a stamping process. The conductive adhesive member 70 may have a smaller area than top surface of the light emitting device 20. The conductive adhesive member 70 may include an ACF.

Referring to FIG. 6B, the method may include stacking and pressurizing the Zener diode 60 on the conductive adhesive member 70, and curing the conductive adhesive member 70. When the Zener diode 60 is stacked and pressurized on the conductive adhesive member 70, the conductive adhesive member 70 may be spread to contact the bottom of a lower electrode 62 of the Zener diode 60. Further, the conductive adhesive member 70 may surround a part of side surfaces of the Zener diode 60. The curing of the conductive adhesive member 70 may include heating the package body 10 in which the conductive adhesive member 70 is provided between the second lead frame 14 and the Zener diode 60 in a curing oven. For example, the conductive adhesive member 70 may be heated for about 1 to 2 hours at about 150° C.

Referring to FIG. 6C, a first electrode 22 and a second electrode 24 of the light emitting device 20 may be electrically connected with a first lead frame 12 and a second lead frame 14, respectively, and an upper electrode 61 of the Zener diode 60 may be electrically connected with the first lead frame 12. The electrically connecting of the first and second electrodes 22 and 24 of the light emitting device 20 with the first and second lead frames 12 and 14 may include using bonding wires W. For example, the first electrode 22 of the light emitting device 20 may be electrically connected with the first lead frame 12 using a corresponding bonding wire W, and the second electrode 24 of the light emitting device 20 may be electrically connected with the second lead frame 14 using a corresponding bonding wire W. Further, the electrically connecting of the upper electrode 61 of the Zener diode 60 with the first lead frame 12 may include using a corresponding bonding wire W. For example, the upper electrode 61 of the Zener diode 60 may be electrically connected with the first lead frame 12 using a corresponding bonding wire W. The bonding wires W may include gold (Au).

Then, the processes described with reference to FIGS. 4E to 4I may be performed. Accordingly, the light emitting device package 10C such as shown in FIG. 3B may be formed.

As described above, in the light emitting device packages 10A, 10B and 10C according to the various implementations of the inventive concept, it may be prevented that the red phosphor is excited by light emitted from the green phosphor in advance since the red phosphor sheet is attached on the blue LED which emits blue light, and the green phosphor molding portion is formed to cover the blue LED and the red phosphor sheet. That is, since absorbing part of the light emitted from the green phosphor into the red phosphor can be prevented, light flux of the green light can be improved.

In addition, in the light emitting device packages 10A, 10B and 10C according to the various implementations of the inventive concept, uniform white light can be embodied and thus total yield can be improved by using a phosphor sheet which may uniformly distribute a desired amount of (red) phosphor according to light emitting device packages to be designed and improving light distribution characteristics and color dispersion of the light emitting device package.

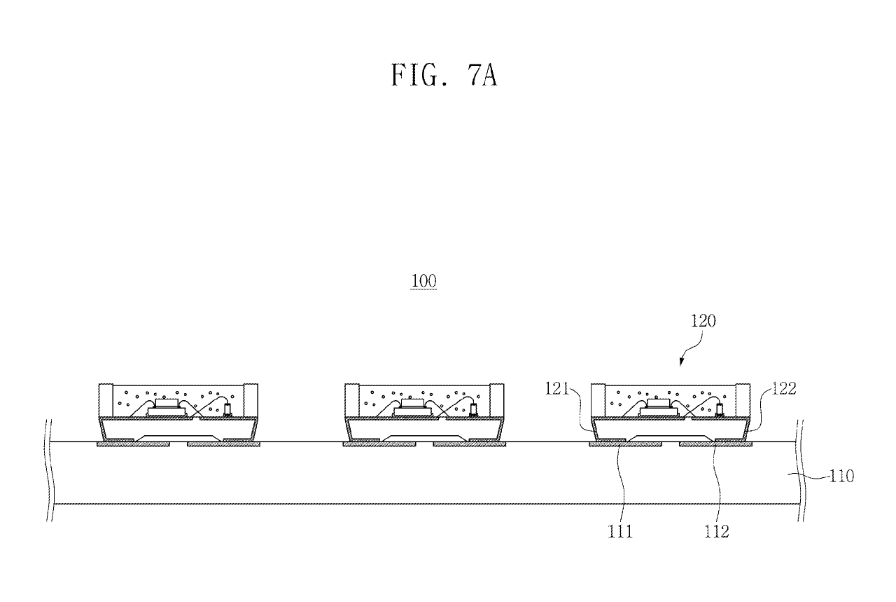

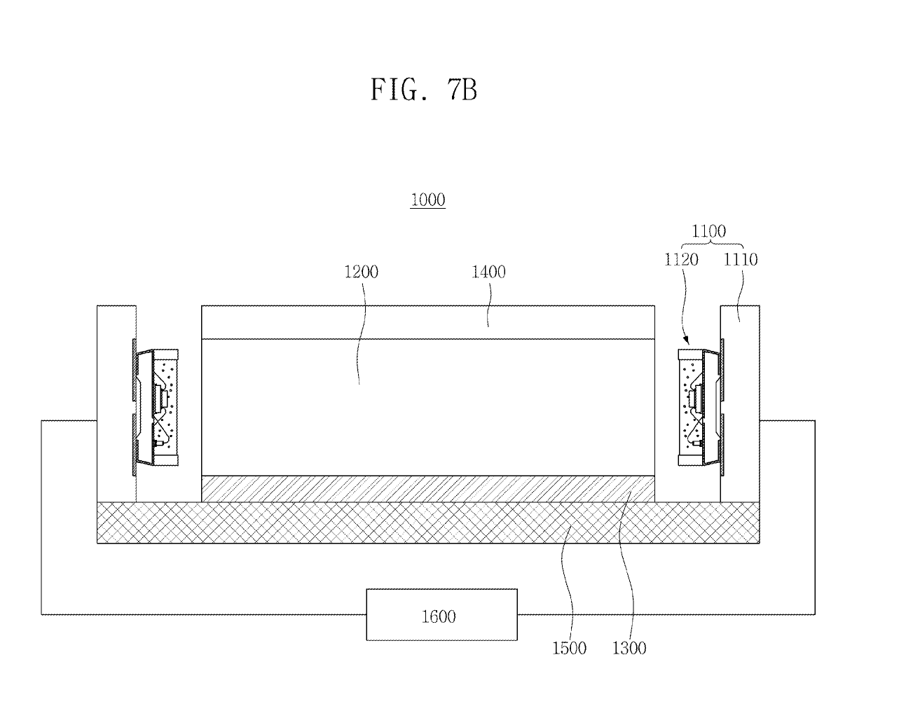

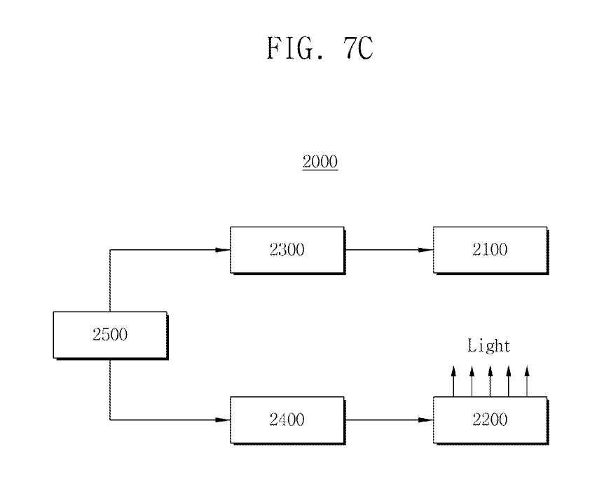

FIG. 7A is a schematic diagram illustrating a light emitting module 100 including at least one of light emitting device packages in accordance with various implementations of the instant application. The light emitting module 100 includes a plurality of light emitting device packages 120 disposed on a module substrate 110.

The light emitting device packages 120 may include at least one of the light emitting device packages 10A, 10B and 10C shown in FIGS. 1A to 3B. The light emitting device packages 120 may be disposed on the module substrate 110 in an array form. Lead frames 121 and 122 of the light emitting device packages 120 may be electrically connected with wiring patterns 111 and 112 on the module substrate 110. For example, the lead frames 121 and 122 of the light emitting device packages 120 may be flip-chip bonded with the wiring patterns 111 and 112 on the module substrate 110.

FIG. 7B is a schematic diagram illustrating a back-light unit 1000 including at least one of light emitting device packages in accordance with various implementations of the inventive concept. The back-light unit 1000 includes a light emitting module 1100 which emits light, a light guide panel 1200 which induces light emitted from the light emitting module 1100, a reflecting plate 1300 disposed under the light guide panel 1200, an optical sheet 1400 disposed on the light guide panel 1200, a lower chassis 1500 which support the back-light unit 1000 and on which the light emitting module 1100 is seated, and a driving unit 1600.

The light emitting module 1100 may be disposed on side surfaces of the light guide panel 1200, and formed in a bar shape including one or more light emitting device packages 1120 on the module substrate 1110 in which wiring patterns are formed. The plurality of light emitting modules 1100 may be disposed along four side surfaces of the light guide panel 1200. The one or more light emitting device packages 1120 may include any one of the light emitting device packages 10A, 10B and 10C shown in FIGS. 1A to 3B. The light guide panel 1200 may have a plate structure having a rectangular parallelepiped shape, and pass light emitted from the light emitting module 1100. The light guide panel 1200 may uniformly spread light received from side surfaces thereof to retain light brightness and color uniformity. The light guide panel 1200 may include a transparent material such as PMMA. The reflecting plate 1300 may be disposed under the light guide panel 1200 and reflect light emitted from the light guide panel 1200 in a downward direction to an upward direction. The optical sheet 1400 may vertically emit light incident at a predetermined angle from the light guide panel 1200. The optical sheet 1400 may include a diffusion sheet, a prism sheet and a protection sheet. The lower chassis 1500 may be formed to support the back-light unit 1000 and seat the light emitting module 1100. The lower chassis 1500 may include a metal material for heat dissipation. The driving unit 1600 may be electrically connected with the plurality of light emitting modules 1100 to control a drive signal which drives each of the light emitting modules 1100. The drive signal is a current signal which is injected into the corresponding light emitting module 1100, and the magnitude of the signal may be adjusted to drive the corresponding light emitting module 1100.

FIG. 7C is a schematic diagram illustrating a device assembly 2000 including at least one of light emitting device packages in accordance with various implementations of the instant application. The device assembly 2000 includes a liquid crystal panel 2100 which displays an image, a back-light unit 2200 which supplies light to the liquid crystal panel 2100, a control circuit unit 2300 which supplies a control signal, a gate signal and a data signal to the liquid crystal panel 2100, an inverter circuit unit 2400 which controls power supply of the back-light unit 2200, and a system circuit unit 2500 which controls the control circuit unit 2300 and the inverter circuit unit 2400. The device assembly 2000 may include a display device assembly.

The liquid crystal panel 2100 may include a plurality of pixels, and display an image using a gate signal and a data signal. The back-light unit 2200 may supply light to the liquid crystal panel 2100, and thus the back-light unit 2200 may include a light emitting module including a plurality of light emitting device packages disposed on a module substrate. The plurality of light emitting device packages may include any one of the light emitting device packages 10A, 10B and 10C shown in FIGS. 1A to 3B. The control circuit unit 2300 may be formed in the form of a printed circuit board (PCB) including a timing controller, a driving integrated circuit and the like, and may supply a plurality of control signals and RGB signals to the liquid crystal panel 2100 to display an image. Further, the control circuit unit 2300 may supply an original or modulated dimming signal for the back-light unit control input from the system circuit unit 2500, to the inverter circuit unit 2400. The inverter circuit unit 2400 may control light emitting of the back-light unit 2200 using the dimming signal input from the control circuit unit 2300. The system circuit unit 2500 as an external interface circuit such as a TV system or graphic card, may supply an image signal and a plurality of drive signals to the control circuit unit 2300, and supply the dimming signal to the control circuit unit 2300.

The light emitting device packages according to the various implementations of the instant application may prevent a red phosphor from being excited by light emitted from a green phosphor in advance as a red phosphor sheet which emits red light is attached on a blue LED which emits blue light, and a green phosphor molding portion which emits green light is formed on the red phosphor sheet. Therefore, since absorbing part of the light emitted from the green phosphor into the red phosphor can be prevented, and light flux of the green light can be improved.

In addition, by using the phosphor sheet which can uniformly distribute a desired amount of phosphor according to the light emitting device package to be designed, light distribution characteristics and color dispersion of the light emitting device package can be improved. Therefore, in the light emitting device package, uniform white light can be embodied and thus total yield can be improved.

The foregoing is illustrative of implementations and is not to be construed as limiting thereof. Although a few implementations have been described, those skilled in the art will readily appreciate that many modifications are possible in implementations without materially departing from the novel teachings and advantages. Accordingly, all such modifications are intended to be included within the scope of the instant application as defined in the claims. In the claims, means-plus-function clauses are intended to cover the structures described herein as performing the recited function, and not only structural equivalents but also equivalent structures. Therefore, it is to be understood that the foregoing is illustrative of various implementations and is not to be construed as limited to the specific implementations disclosed, and that modifications to the disclosed implementations, as well as other implementations, are intended to be included within the scope of the appended claims.

What is claimed is:

1. A light emitting device package, comprising:
a package body including a first lead frame;
a light emitting device mounted on the package body, the light emitting device including a first electrode formed on a top surface thereof;
a first bonding wire configured to electrically connect the first electrode with the first lead frame;
a phosphor sheet attached on the light emitting device; and
a phosphor molding portion to cover the light emitting device and the phosphor sheet.

2. The package of claim 1, further comprising a cavity located in the middle of the package body.

3. The package of claim 1, wherein the phosphor sheet has the same area as the top surface of the light emitting device.

4. The package of claim 1, wherein side surfaces of the phosphor sheet are vertically arranged with respect to side surfaces of the light emitting device.

5. The package of claim 2, further comprising:
a second lead frame on the package body,
a portion of the first lead frame and a portion of the second lead frame are exposed in the cavity.

6. The package of claim 5, wherein the light emitting device is mounted on the exposed portion of the second lead frame.

7. The package of claim 6, further comprising:
a second electrode formed on the top surface the light emitting device; and
a second bonding wire configured to electrically connect the second electrode with the second lead frame.

8. The package of claim 6, further comprising a chip adhesive member interposed between the light emitting device and the second lead frame.

9. The package of claim 8, wherein the chip adhesive member surrounds a part of side surfaces of the light emitting device.

10. The package of claim 5, further comprising a Zener diode disposed on the first lead frame.

11. The package of claim 10, wherein the Zener diode includes an upper electrode electrically connected with the second lead frame and a lower electrode electrically connected with the first lead frame.

12. The package of claim 11, wherein the upper electrode of the Zener diode is electrically connected with the second lead frame using a bonding wire, and the lower electrode is electrically connected with the first lead frame using a conductive adhesive member.

13. A light emitting device package, comprising:
a package body including a cavity and first and second lead frames exposed on a bottom of the cavity;
a light emitting device including first and second electrodes mounted in the cavity and formed on a top surface thereof;
a Zener diode mounted on the first lead frame and having an upper electrode and a lower electrode;
first and second bonding wires to electrically connect the first and second electrodes of the light emitting device with the first and second lead frames, respectively, and a third bonding wire to electrically connect the upper electrode of the Zener diode with the second lead frame;
a red phosphor sheet attached on the light emitting device; and
a green phosphor molding portion filling the cavity.

14. The package of claim 13, wherein the red phosphor sheet does not cover side surfaces of the light emitting device.

15. The package of claim 14, wherein the green phosphor molding portion covers the side surfaces of the light emitting device and side surfaces of the red phosphor sheet.

16. A light emitting device package, comprising:
a package body including a lead frame;
a light emitting device mounted on the package body;
a bump configured to electrically connect an electrode formed on a bottom surface of the light emitting device with the lead frame;
a phosphor sheet attached on the light emitting device; and
a phosphor molding portion to cover the light emitting device and the phosphor sheet.

17. The package of claim 16, further comprising a cavity located in the middle of the package body.

18. The package of claim 16, wherein the phosphor sheet has the same area as the top surface of the light emitting device.

19. The package of claim 16, wherein side surfaces of the phosphor sheet are vertically arranged with respect to side surfaces of the light emitting device.

20. A back-light unit comprising:
a light emitting module configured to emit light;
a light guide panel configured to induce the light emitted from the light emitting module;
a reflecting plate disposed under the light guide panel and configured to reflect light emitted from the light guide panel;
a lower chassis configured to support the back-light unit and on which the light emitting module is seated; and
a drive unit connected to the light emitting module and configured to control a drive signal which drives the light emitting module,
wherein the light emitting module includes the light emitting device package of claim 1.
